(19) United States
(12) Patent Application Publication
(10) Pub. No.: US 2026/0247584 A1
(43) Pub. Date: Aug. 20, 2026

(54) COMBINED HEAT DISSIPATION SYSTEM AND SERVER

(71) Applicants: Inventec (Pudong) Technology Corporation, Shanghai (CN); INVENTEC CORPORATION, Taipei (TW)

(72) Inventors: Qi Zhang, Shanghai (CN); Jiangjun Wu, Shanghai (CN)

(21) Appl. No.: 19/204,605

(22) Filed: May 11, 2025

(30) Foreign Application Priority Data
Feb. 14, 2025 (CN) 202510164082.1

(51) Int. Cl. H05K 7/20; F28F 9/22

(52) U.S. Cl. CPC H05K 7/20836; H05K 7/20727; H05K 7/20809; F28F 9/22

(57) ABSTRACT

A combined heat dissipation system includes a fuel tank, a heat exchanger, a pump, a fan, a first temperature detecting device, and a controller. The fuel tank, the heat exchanger, and the pump achieve a liquid cooling cycle. The controller turns on the pump to cool a heat dissipation area through the liquid cooling cycle when the actual temperature of the heat dissipation area of the device to be heat dissipated is higher than the starting temperature. After turning on the pump, the controller adjusts the output flow of the pump according to the actual temperature to match the cooling quantity of the liquid cooling cycle with the heating quantity of the heat dissipation area. The controller turns on the fan to cool the heat exchanger and pump when the actual temperature is higher than a safe temperature to cool the heat exchanger and the pump.

### CROSS-REFERENCES TO RELATED APPLICATIONS

This application claims priority to Chinese patent application No. 2025101640821, filed on Feb. 14, 2025, the content of which is hereby incorporated by reference in its entirety.

### TECHNICAL FIELD

The present disclosure relates to the technical field of heat dissipation, and more particularly, to a combined heat dissipation system, and a server.

### BACKGROUND

With the innovation and development of technologies such as artificial intelligence, big data, and blockchain, especially the promotion and advancement of technologies such as ChatGPT (Chat Generative Pre-trained Transformer), the demand for data resources in terms of storage, computing, and applications has rapidly expanded. The rapid expansion of demand has in turn given birth to the deployment of high-power servers equipped with artificial intelligence computing capabilities. The demand for high-power servers is growing across various industries, and the power consumption of various electronic components in high-power servers is also continuously increasing, so conventional heat dissipation methods no longer meet heat dissipation requirements of high-power servers.

### SUMMARY

In a first aspect, the present disclosure provides a combined heat dissipation system. The combined heat dissipation system includes:
a fuel tank, a surface of the fuel tank covers at least a heat dissipation area of a device to be heat dissipated;
a heat exchanger, a liquid inlet of the heat exchanger is connected to a liquid outlet of the fuel tank;
a pump, a liquid inlet of the pump is connected to a liquid outlet of the heat exchanger, and a liquid outlet of the pump is connected to a liquid inlet of the fuel tank;
a fan, the fan is configured with a blowing area covering areas where the heat exchanger and the pump are located;
a first temperature detecting device, the first temperature detecting device is configured to detect an actual temperature of the heat dissipation area of the device to be heat dissipated; and
a controller, the controller is connected to the first temperature detecting device, the pump and the fan, and configured to:
receive the actual temperature and turn on the pump when the actual temperature is higher than a starting temperature;
adjust an output flow of the pump according to the actual temperature; and
turn on the fan to cool the heat exchanger and pump when the actual temperature is higher than a safe temperature, the starting temperature is lower than the safe temperature.

In a second aspect, the present disclosure provides a server. The server includes:
a chassis, the chassis has an accommodating space;
a motherboard, the motherboard is provided with at least one cold plate and the motherboard is arranged in the accommodating space; and
a combined heat dissipation system, the combined heat dissipation system includes the following components set in the accommodating space:
a fuel tank, a surface of the fuel tank covers at least the area of the cold plate;
a heat exchanger, a liquid inlet of the heat exchanger is connected to a liquid outlet of the fuel tank;
a pump, a liquid inlet of the pump is connected to a liquid outlet of the heat exchanger, and a liquid outlet of the pump is connected to a liquid inlet of the fuel tank;
a fan, the fan is configured with a blowing area covering areas where the heat exchanger and the pump are located;
a first temperature detecting device, the first temperature detecting device is configured to detect an actual temperature of the cold plate; and
a controller, the controller is connected to the first temperature detecting device, the pump and the fan, and configured to receive the actual temperature and turn on the pump when the actual temperature is higher than the starting temperature, adjust an output flow of the pump according to the actual temperature and turn on the fan to cool the heat exchanger and pump when the actual temperature is higher than the safe temperature, the starting temperature is lower than the safe temperature.

The details of the various embodiments of the present disclosure will be illustrated with the accompanying drawings and description below, based on which, other features, problems to be solved, and beneficial effects of the disclosure will be readily understood by those skilled in the art.

### BRIEF DESCRIPTION OF THE DRAWINGS

In order to describe the technical solutions of the embodiments of the present disclosure or the conventional art more clearly, the accompanying drawings required for describing the embodiments or for describing the conventional art will be briefly introduced as follows. Apparently, the accompanying drawings, in the following description, illustrate merely some embodiments of the present disclosure, and for a person of ordinary skill in the art, other drawings can also be obtained according to these accompanying drawings without making any creative efforts.

FIG. 1 is a structural block diagram of a combined heat dissipation system in an embodiment.

FIG. 2 is a structural block diagram of another combined heat dissipation system in another embodiment.

FIG. 3 is a structural block diagram of a server in an embodiment.

### DETAILED DESCRIPTION OF THE EMBODIMENTS

In order to understand the present disclosure, the technical solutions of embodiments of the present disclosure will be described clearly and completely below with reference to the accompanying drawings of the embodiments of the present disclosure. The embodiments of the present disclosure are given in the accompanying drawings. However, the present disclosure can be realized in many different forms and is not limited to the embodiments described herein. On the contrary, these embodiments are provided to make the present disclosure more thorough and comprehensive.

Unless otherwise defined, all technical and scientific terms used in the present disclosure have the same meaning as commonly understood by those skilled in the art belonging to the present disclosure. It should be understood that the specific terms described herein are merely for explaining the present disclosure, but not intended to limit the present disclosure.

It should be understood that the terms “first”, “second”, etc. may be used herein to describe various elements, but these elements are not limited by these terms. These terms are used only to distinguish the first element from another element. For example, without departing from the scope of the present disclosure, the first temperature sensor may be referred to as the second temperature sensor, and similarly, the second temperature sensor may be referred to as the first temperature sensor. Both the first temperature sensor and the second temperature sensor are temperature sensors, but they are not the same temperature sensor.

It should be understood that in the following embodiments, if the connected circuits, modules, and units, etc. transmit electrical signals or data to each other, the term “connection” is understood to mean “electrical connection”, “communication connection”, etc.

It should be understood that the term “at least one” means one or more, the term “multiple” means two or more, and the term “at least part of an element” means part or all of an element.

As used herein, the singular forms “one”, “a” and “said/that” may also include the plural form, unless the context clearly indicates otherwise. It should also be understood that the terms “includes/contains” or “has” etc. designate the presence of the stated feature, whole, step, operation, component, part or combination thereof, but do not preclude the presence or addition of one or more other features, wholes, steps, operations, components, parts or combinations thereof. Also, as used in this specification, the term “and/or” includes any and all combinations of the items listed therein.

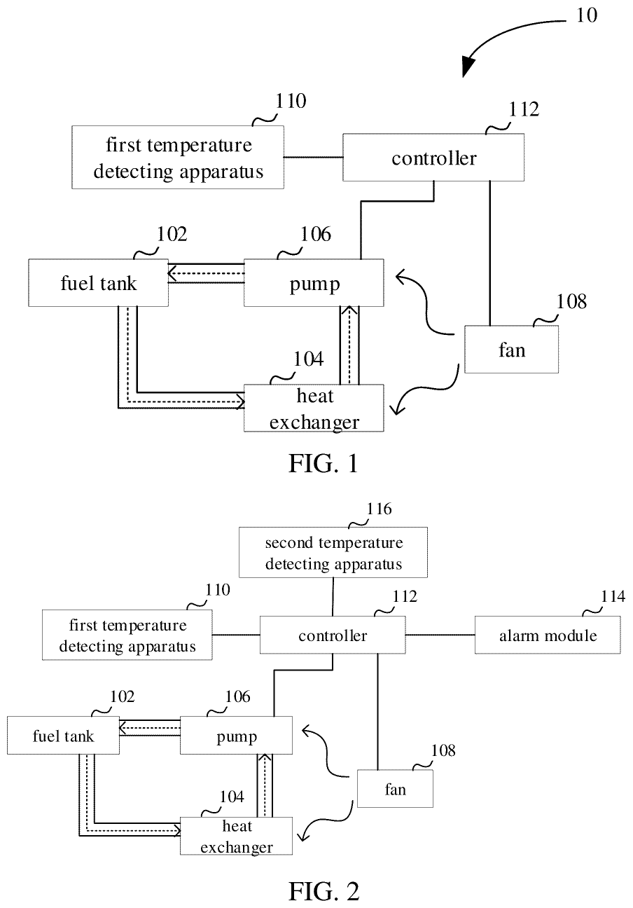

In an embodiment, as shown in FIG. 1, the present disclosure provides a combined heat dissipation system 10. The combined heat dissipation system includes a fuel tank 102, a heat exchanger 104, a pump 106, a fan 108, a first temperature detecting device 110, and a controller 112.

A surface of the fuel tank 102 covers at least a heat dissipation area of a device to be heat dissipated.

A liquid inlet of the heat exchanger 104 is connected to a liquid outlet of the fuel tank 102.

A liquid inlet of the pump 106 is connected to a liquid outlet of the heat exchanger 104, and a liquid outlet of the pump 106 is connected to a liquid inlet of the fuel tank 102.

A blowing area of the fan 108 covers areas where the heat exchanger 104 and the pump 106 are located.

The first temperature detecting device 110 is configured to detect an actual temperature of the heat dissipation area of the device to be heat dissipated.

The controller 112 is connected to the first temperature detecting device 110, the pump 106 and the fan 108, respectively. The controller 112 is configured to receive the actual temperature and turn on the pump when the actual temperature is higher than a starting temperature. The controller 112 is also configured to adjust the output flow of the pump 106 according to the actual temperature. The controller 112 is also configured to turn on the fan 108 to cool the heat exchanger 104 and pump 106 when the actual temperature is higher than a safe temperature. The starting temperature is lower than the safe temperature.

The liquid cooling oil in the fuel tank 102 flows into the heat exchanger 104 after heat exchange with the heat dissipation area, and is cooled in the heat exchanger 104. The cooled liquid cooling oil is extracted by the pump 106, and then flows into the fuel tank 102, thereby achieving cooling through the liquid cooling cycle.

It indicates that the temperature of the liquid cooling oil in the oil tank 102 has risen to a level that requires cooling when the actual temperature of the heat dissipation area is higher than the starting temperature, that is, the heat dissipation area needs to be cooled. In this case, the controller 112 can turn on the pump 106 to start the liquid cooling cycle described above, and the cooling is realized by removing the heat in the heat dissipation area through the liquid cooling oil. When the actual temperature of the heat dissipation area is higher than the starting temperature, and the actual temperature is lower than the safe temperature, the controller 112 can adjust the output flow of the pump 106 according to the actual temperature. Specifically, the output flow rate of the pump 106 can be gradually increased as the actual temperature increases, so as to promote the liquid cooling cycle, and the output flow rate of the pump 106 can be gradually decreased as the actual temperature decreases to reduce the waste of energy. When the actual temperature of the heat dissipation area is higher than the safe temperature, it indicates that the cooling rate of the liquid cooling oil in the fuel tank 102 is lower than the heating rate of the heat dissipation area. At this time, the controller 112 turns on the fan 108. Since the blowing area of the fan 108 covers the areas where the heat exchanger 104 and the pump 106 are located, after the fan 108 is turned on, the fan 108 can cool the heat exchanger 104 and the pump 106, thereby assisting in the cooling of the liquid cooling oil.

The combined heat dissipation system described above includes the fuel tank 102, the heat exchanger 104, the pump 106, the fan 108, the first temperature detecting device 110, and the controller 112, where the fuel tank 102, the heat exchanger 104, and the pump 106 can achieve a liquid cooling cycle, the controller 112 can turn on the pump 106 to cool the heat dissipation area through a liquid cooling cycle when the actual temperature of the heat dissipation area of the device to be heat dissipated is higher than the starting temperature. After turning on the pump 106, the controller 112 can also adjust the output flow of the pump 106 according to the actual temperature to match the cooling quantity of the liquid cooling cycle with the heating quantity of the heat dissipation area. The controller 112 can also turn on the fan 108 to cool the heat exchanger 104 and pump 106 when the actual temperature is higher than a safe temperature. Therefore, the combined heat dissipation system 10 can adjust the cooling quantity according to the heating quantity of the device to be heat dissipated. Comparing with the single heat dissipation system, the combined heat dissipation system can meet the heat dissipation requirements of both low-power servers and high-power servers, achieving a wide range of applications.

In an embodiment, the controller is further configured to increase the rotational speed of the fan when the actual temperature is higher than a temperature threshold, where the temperature threshold is higher than the safe temperature.

When the actual temperature of the heat dissipation area is higher than the temperature threshold, it indicates that the blowing heat dissipation that the fan 108 provides to the heat exchanger 104 and the pump 106, and the liquid cooling cycle formed by the fuel tank 102, the heat exchanger 104 and the pump 106 are no longer capable of meeting the current heat dissipation requirements. At this time, auxiliary cooling can be achieved by increasing the rotational speed of the fan 108.

Further, different temperature thresholds can be set to achieve step-by-step adjustment of heat dissipation.

In an embodiment, the controller 112 is also configured to adjust the rotational speed of the fan 108 according to the actual temperature after the fan 108 is turned on.

Specifically, after the fan 108 is turned on, the controller 112 can increase the rotational speed of the fan 108 until the maximum rotational speed of the fan 108 is reached when the actual temperature is increased. The controller 112 can also lower the rotation speed of the fan 108 until the fan 108 is turned off. It indicates that the actual temperature at this time falls back to a range below the safe temperature when fan 108 is turned off.

In an embodiment, as shown in FIG. 2, the combined heat dissipation system further includes an alarm module 114.

The alarm module 114 is connected to the controller 112.

The controller 112 is also configured to drive the alarm module 114 to perform an alarm action when the actual temperature is continuously higher than the temperature threshold within a preset time.

The preset time can be determined based on the heat dissipation capability of the combined heat dissipation system 10. Specifically, if the actual temperature is higher than the temperature threshold and the combined heat dissipation system 10 can reduce the actual temperature to a range below the temperature threshold within 10 minutes, the preset time can be set correspondingly to 10 minutes, 12 minutes or 15 minutes. It can be understood that, the specific values of the preset time are only examples and are not limiting. The preset time can also be determined as 5 minutes, 1 hour, 5 hours, etc. according to the actual heat dissipation capacity of the combined heat dissipation system 10. It can be understood that, the preset time can also be determined based on actual heat dissipation requirements and device performance of the combined heat dissipation system 10.

The actual temperature being continuously higher than the temperature threshold indicates that the combined heat dissipation system 10 cannot reduce the actual temperature of the heat dissipation area of the device to be heat dissipated to a safe and proper temperature range, posing a safety hazard.

The alarm module 114 can remind the staff through sound and light alarm, and can also transmit the temperature information at this time to a terminal device, so that the staff can obtain the information that “the actual temperature is higher than the temperature threshold” through a pop-up window displayed on the terminal device and the like. The staff can thus take corresponding measures in time when the actual temperature is higher than the temperature threshold.

In an embodiment, as shown in FIG. 2, the combined heat dissipation system further includes a second temperature detecting device 116.

The second temperature detecting device 116 is configured to detect an environmental temperature of the device to be heat dissipated.

The controller 112 is connected to the second temperature detecting device 116, and is further configured to receive and adjust the starting temperature, the safe temperature, and the temperature threshold according to the environmental temperature. The environmental temperature is positively correlated with the starting temperature, the safety temperature and the temperature threshold.

The higher the environmental temperature of the device to be heat dissipated is, the higher the starting temperature, the safety temperature and the temperature threshold can be adjusted correspondingly to avoid repeatedly starting the pump 106 and fan 108, and extend the service life of the combined heat dissipation system 10.

In an embodiment, a pipe connecting the fuel tank to the heat exchanger, and a pipe connecting the fuel tank to the pump are transparent pipes.

The transparent pipe can reduce the flow resistance of the liquid cooling oil, so that the flow of the liquid cooling oil in the pipe is smooth, thereby improving the cooling efficiency of the combined heat dissipation system 10. The transparent tube can also reduce the allowable noise of the heat dissipation system 10 to achieve silent operation.

The staff can directly observe the flow of the liquid cooling oil through the transparent pipe, so as to quickly judge the flow rate, bubbles and other conditions of the liquid cooling oil, and timely identify a failure location when a failure of the liquid cooling oil occurs, such as leakage, blockage, and oil quality deterioration.

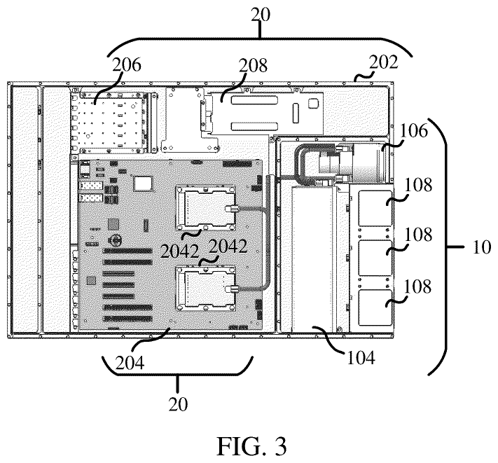

In an embodiment, as shown in FIG. 3, the present disclosure provides a server, and the server includes a chassis 202, a motherboard 204 and a combined heat dissipation system 10.

The chassis 202 has an accommodating space.

The motherboard 204 is provided with at least one cold plate 2042, and the motherboard 204 is arranged in the accommodating space.

The combined heat dissipation system 10 includes the following components arranged in the accommodating space: a fuel tank 102, a heat exchanger 104, a pump 106, a fan 108, a first temperature detecting device 110, and a controller 112.

A surface of the fuel tank 102 covers at least an area where the cold plate 2042 is located.

A liquid inlet of the heat exchanger 104 is connected to a liquid outlet of the fuel tank 102.

A liquid inlet of the pump 106 is connected to a liquid outlet of the heat exchanger 104, and a liquid outlet of the pump 106 is connected to a liquid inlet of the fuel tank 102.

A blowing area of the fan 108 covers the areas where the heat exchanger 104 and the pump 106 are located.

The first temperature detecting device 110 is configured to detect an actual temperature of the cold plate 2042.

The controller 112 is connected to the first temperature detecting device 110, the pump 106 and the fan 108, respectively. The controller 112 is configured to receive the actual temperature and turn on the pump 106 when the actual temperature is higher than the starting temperature. The controller 112 is also configured to adjust the output flow of the pump 106 according to the actual temperature. The controller 112 is also configured to turn on the fan 108 to cool the heat exchanger 104 and pump 106 when the actual temperature is higher than the safe temperature. The starting temperature is lower than the safe temperature.

The cold plate 2042 has excellent thermal conductivity to achieve efficient heat exchange, thereby achieving efficient cooling and heat dissipation. Further, according to the volume size of the server 20 and the heat dissipation requirements of the server 20, a plurality of cold plates 2042 can be provided, thus, multiple points of cooling are realized, so as to further improve the efficiency of the cooling and the heat dissipation.

Correspondingly, when there are a plurality of the cold plates 2042, the number of the first temperature detecting device 110 is consistent with the number of the cold plates 2042, so as to realize multi-point temperature detection.

When the actual temperature of the cold plates 2042 received is higher than the starting temperature, the controller 112 can turn on the pump to cool the cold plate 2042 through the liquid cooling cycle, thereby realizing heat dissipation and cooling of the motherboard 204. After turning on the pump 106, the controller 112 can also adjust the output flow of the pump 106 according to the actual temperature to match the cooling quantity of the liquid cooling cycle with the heating quantity of the cold plates 2042, and real-time heat dissipation and cooling of the temperature of the motherboard 204 can be thus performed. The controller 112 can also turn on the fan 108 to cool the heat exchanger 104 and pump 106 when the actual temperature is higher than a safe temperature, thereby improving the heat dissipation and cooling efficiency of the motherboard 204. The heat dissipation and cooling of the server 20 can be achieved through the heat dissipation and cooling of the temperature of the motherboard 204.

In an embodiment, as shown in FIG. 3, the server 20 also includes a hard disk 206 and a power supply 208, and a surface of the fuel tank 102 covers areas where the hard disk 206 and the power supply 208 are located.

During the operation of the server 20, the hard disk 206 and the power supply 208 also emit heat. Therefore, the coverage of the fuel tank 102 can be extended to cover the areas where the hard disk 206 and the power supply 208 are located, thereby further improving the heat dissipation and cooling efficiency of the server 20.

In an embodiment, as shown in FIG. 3, the controller 112 is further configured to increase the rotational speed of the fan 108 when the actual temperature is higher than a temperature threshold, where the temperature threshold is higher than the safe temperature.

Optionally, the fan 108 can be installed in the chassis 202 of the server 20 and disposed close to the heat exchanger 104 and the pump 106 to better cool the heat exchanger 104 and the pump 106. The working efficiency of the heat exchanger 104 and the pump 106 is therefore improved, so as to achieve the effect of improving the heat dissipation and cooling efficiency of the server 20.

Optionally, the fan 108 can be installed outside the chassis 202 of the server 20 and disposed close to the heat exchanger 104 and the pump 106, which facilitates maintenance and cleaning of the fan 108 to ensure that the fan 108 is in an optimal operating state.

In an embodiment, the controller 112 is also configured to adjust the rotational speed of the fan 108 according to the actual temperature after the fan 108 is turned on.

Specifically, after the fan 108 is turned on, the controller 112 can increase the rotational speed of the fan 108 until the maximum rotational speed of the fan 108 is reached when the actual temperature is increased. The controller 112 can also lower the rotation speed of the fan 108 until the fan 108 is turned off. It indicates that the actual temperature at this time falls back to a range below the safe temperature when fan 108 is turned off.

In an embodiment, as shown in FIG. 3, the server 20 includes a plurality of fans 108.

The plurality of fans 108 can improve the cooling efficiency of the heat exchanger 104 and pump 106.

Exemplarily, the number of fans 108 that are put into operation can be gradually increased as the actual temperature increases when the actual temperature is higher than the safe temperature. When the actual temperature is higher than the safe temperature, all the fans 108 can be turned on at the same time, and the rotation speed of each fan 108 can be gradually increased as the actual temperature increases. It can be understood that, when there are a plurality of fans 108, the startup of each fan 108 and the adjustment of the rotational speed can follow other modes, but the overall adjustment rule is that when the actual temperature is higher than the safe temperature, the number of fans 108 and/or the rotational speed of the activated fan 108 is increased as the actual temperature increases.

In an embodiment, the combined heat dissipation system 10 further includes a second temperature detecting device 116.

The second temperature detecting device is arranged on the outer wall of the chassis and is configured to detect an environmental temperature of the server.

The controller 112 is connected to the second temperature detecting device 116, and is further configured to receive and adjust the starting temperature, the safe temperature, and the temperature threshold according to the environmental temperature. The environmental temperature is positively correlated with the starting temperature, the safety temperature and the temperature threshold.

The higher the environmental temperature of the server 20 is, the higher the starting temperature, the safety temperature and the temperature threshold can be adjusted correspondingly to avoid repeatedly starting the pump 106 and fan 108, and extend the service life of the combined heat dissipation system 10.

In an embodiment, the heat exchanger 104, the pump 106 and the fan 108 are located on one side of the motherboard 204 and are arranged near the cold plate 2042, which can reduce the number of pipes laid for transporting the liquid cooling oil, thereby reducing material costs.

In the description of the present specification, the description with reference to the terms “some embodiments”, “other embodiments”, and the like indicates that specific features, structures, materials, or characteristics described in conjunction with the embodiment or example are included in at least one embodiment or example of the present application. In the specification, schematic descriptions of the above terms do not necessarily refer to the same embodiment or example.

The various technical features of the above-described embodiments may be combined arbitrarily, and all possible combinations of the various technical features of the above-described embodiments have not been described for the sake of conciseness of description; however, as long as there is no contradiction in the combinations of these technical features, they should be considered to be within the scope of the present specification as recorded herein.

The above-described embodiments express only several embodiments of the present application, which are described in a more specific and detailed manner, but are not to be construed as a limitation of the scope of the present application. It should be pointed out that, for a person of ordinary skill in the art, several deformations and improvements can be made without departing from the conception of the present application, all of which fall within the scope of protection of the present application. Therefore, the scope of protection of this application shall be subject to the attached claims.

What is claimed is:

1. A combined heat dissipation system, comprising:
a fuel tank, a surface of the fuel tank covering at least a heat dissipation area of a device to be heat dissipated;
a heat exchanger, a liquid inlet of the heat exchanger being connected to a liquid outlet of the fuel tank;
a pump, a liquid inlet of the pump being connected to a liquid outlet of the heat exchanger, and a liquid outlet of the pump is connected to a liquid inlet of the fuel tank;
a fan, the fan is configured with a blowing area covering areas where the heat exchanger and the pump are located;
a first temperature detecting device, the first temperature detecting device being configured to detect an actual temperature of the heat dissipation area of the device to be heat dissipated; and
a controller, the controller being connected to the first temperature detecting device, the pump and the fan, and configured to:
receive the actual temperature and turn on the pump when the actual temperature is higher than a starting temperature;
adjust an output flow of the pump according to the actual temperature; and
turn on the fan to cool the heat exchanger and pump when the actual temperature is higher than a safe temperature, the starting temperature being lower than the safe temperature.

2. The combined heat dissipation system of claim 1, wherein the controller is further configured to increase a rotational speed of the fan when the actual temperature is higher than a temperature threshold, the temperature threshold being higher than the safe temperature.

3. The combined heat dissipation system of claim 2, further comprising:
an alarm module, the alarm module being connected to the controller,
wherein the controller is further configured to drive the alarm module to perform an alarm action when the actual temperature is higher than the temperature threshold within a preset time.

4. The combined heat dissipation system of claim 2, further comprising:
a second temperature detecting device, the second temperature detecting device being configured to detect an environmental temperature of the device to be heat dissipated,
wherein the controller is connected to the second temperature detecting device and configured to receive and adjust the starting temperature, the safe temperature, and the temperature threshold according to the environmental temperature, the environmental temperature being positively correlated with the starting temperature, the safety temperature and the temperature threshold.

5. The combined heat dissipation system of claim 1, further comprising:
a pipe connecting the fuel tank to the heat exchanger, and a pipe connecting the fuel tank to the pump are transparent pipes.

6. The combined heat dissipation system of claim 1, wherein the controller is further configured to adjust the rotational speed of the fan according to the actual temperature after the fan is turned on.

7. The combined heat dissipation system of claim 1, wherein the controller is configured to increase the rotational speed of the fan until the maximum rotational speed of the fan is reached when the actual temperature is increased after the fan is turned on.

8. The combined heat dissipation system of claim 1, wherein the controller is configured to lower the rotation speed of the fan until the fan is turned off.

9. The combined heat dissipation system of claim 1, further comprising:
a plurality of fans, the plurality of fans being configured to improve a cooling efficiency of the heat exchanger and pump.

10. The combined heat dissipation system of claim 1, wherein the controller is further configured to implement step-by-step adjustments of heat dissipation according to different temperature thresholds.

11. A server, comprising:
a chassis, the chassis having an accommodating space;
a motherboard, the motherboard being provided with at least one cold plate and motherboard arranged in the accommodating space; and
a combined heat dissipation system, the combined heat dissipation system comprising:
a fuel tank, a surface of the fuel tank covering at least the area of the cold plate;
a heat exchanger, a liquid inlet of the heat exchanger being connected to a liquid outlet of the fuel tank;
a pump, a liquid inlet of the pump being connected to a liquid outlet of the heat exchanger, and a liquid outlet of the pump is connected to a liquid inlet of the fuel tank;
a fan, the fan is configured with a blowing area covering areas where the heat exchanger and the pump are located;
a first temperature detecting device, the first temperature detecting device being configured to detect an actual temperature of the cold plate; and
a controller, the controller being connected to the first temperature detecting device, the pump and the fan, and configured to receive the actual temperature and turn on the pump when the actual temperature is higher than the starting temperature; adjust an output flow of the pump according to the actual temperature; and turn on the fan to cool the heat exchanger and pump when the actual temperature is higher than the safe temperature, the starting temperature being lower than the safe temperature,
wherein the fuel tank, the heat exchanger, the pump, the fan, the first temperature detecting device, and the controller are each arranged in the accommodating space.

12. The server of claim 11, further comprising:
a hard disk and a power supply,
wherein a surface of the fuel tank covers areas where the hard disk and the power supply are located.

13. The server of claim 11, wherein the controller is further configured to increase the rotational speed of the fan when the actual temperature is higher than a temperature threshold, the temperature threshold being higher than the safe temperature.

14. The server of claim 13, wherein the combined heat dissipation system further comprising:
a second temperature detecting device, the second temperature detecting device set on the outer wall of the chassis being configured to detect an environmental temperature of the server
wherein the controller is connected to the second temperature detecting device and configured to receive and adjust the starting temperature, the safe temperature, and the temperature threshold according to the environmental temperature, the environmental temperature being positively correlated with the starting temperature, the safety temperature and the temperature threshold.

15. The server of claim 11, wherein the pump and the fan are located on one side of the motherboard and are arranged near the cold plate.

16. The server of claim 11, wherein the combined heat dissipation system further comprising:
an alarm module, the alarm module being connected to the controller,
wherein the controller is further configured to drive the alarm module to perform an alarm action when the actual temperature is higher than the temperature threshold within a preset time.

17. The server of claim 11, wherein the combined heat dissipation system further comprises:
a pipe connecting the fuel tank to the heat exchanger, and a pipe connecting the fuel tank to the pump are transparent pipes.

18. The server of claim 11, wherein the number of the first temperature detecting device is consistent with the number of the at least one cold plate.

19. The server of claim 11, wherein the fan is installed in the chassis of the server and disposed close to the heat exchanger and the pump.

20. The server of claim 11, wherein the fan is installed outside the chassis of the server and disposed close to the heat exchanger and the pump.
